(19) United States
(12) Patent Application Publication
(10) Pub. No.: US 2010/0068888 A1
(43) Pub. Date: Mar. 18, 2010

(54) DRY ETCHING METHOD

(75) Inventors: Masanobu HONDA, Nirasaki City (JP); Shoichiro Matsuyama, Nirasaki City (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Minato-ku (JP)

(21) Appl. No.: 12/561,952

(22) Filed: Sep. 17, 2009

(30) Foreign Application Priority Data
Sep. 17, 2008 (JP) 2008-238341

(51) Int. Cl. H01L 21/3065

(52) U.S. Cl. 438/719; 257/E21.218

(57) ABSTRACT

A dry etching method includes: mounting a silicon substrate on an electrode arranged in a processing chamber; generating a plasma by discharging an etching gas in the processing chamber; supplying to the electrode a radio frequency power for attracting ions from the plasma; and etching the silicon substrate by the plasma by using an inorganic mask containing silicon as an etching mask. An absolute value of a self-bias voltage generated in the electrode is equal to or smaller than about 280 V, and wherein the etching is carried out while satisfying the following equation: y≦0.0114x+0.171, where x is a pressure inside the processing chamber and y is a power density of the radio frequency power per unit area of the electrode.

### CROSS-REFERENCE TO RELATED APPLICATIONS

This application claims priority to Japanese Patent Application No. 2008-238341 filed on Sep. 17, 2008, the entire contents of which are hereby incorporated by reference.

### FIELD OF THE INVENTION

The present invention relates to a dry etching method of etching a silicon substrate by using a plasma.

### BACKGROUND OF THE INVENTION

When manufacturing semiconductor devices, the processes of forming a thin film on a silicon substrate and lithographing and patterning the thin film by dry etching are repeatedly carried out, and the silicon substrate itself is often dry-etched at the initial stage of the manufacturing processes.

Dry etching of the silicon substrate is mainly carried out for trench formation in silicon, e.g., groove-shaped trenches for device isolation and hole-shaped trenches for capacitor formation. In etching silicon trenches, it is important to control the depth to width ratio (i.e. aspect ratio) and a vertical cross sectional shape of the trench; and especially it is an important issue to prevent bowing etching, which is a barrel-shaped hollow portion of an inner wall of the trench, taper etching, in which a groove gets narrower from top to bottom, and undercut etching below a mask (side etching) and the like. Further, to improve the dimensional accuracy in etching pattern, it is important that a ratio of etching rate of the silicon substrate to that of the etching mask, i.e., mask or etching selectivity or simply selectivity, is sufficiently high.

To solve such technical issue, the etching gas employs a halogen compound gas including hydrogen, such as hydrogen bromide (HBr), or a gaseous mixture in which CHF₃ or the like is added to a halogen gas such as Cl₂. A resist or a silicon oxide (SiO₂) film is employed for the material of the etching mask. As for an etching apparatus, a reactive ion etching (RIE) apparatus is employed, which gives the directivity to ions in the plasma and allows the ions to react with a target object (silicon substrate) (see, e.g., the Japanese Patent Laid-open Application No. 2003-218093).

With ever-increasing demands for high-integration and high-performance of the semiconductor devices manufactured on the silicon substrate, semiconductor elements constituting the devices are made smaller by a scaling rule of about 0.7-times. Therefore, 65 nm and 45 nm design rule (i.e. design standard), which are currently applied to the state-of-the-art semiconductor products, are expected to become about 32 nm in the next-generation products and about 22 nm in the next-next generation products.

If the device design standard approaches to 22 nm in the next-next generation products, a metal insulator semiconductor field effect transistor (MISFET), which is a basic semiconductor device for the large scale integration (LSI) circuits, is highly likely to be changed from a two-dimensional structure (planar structure), in which its channel, source and drain regions are two-dimensionally formed on a main surface of a silicon substrate, to a three-dimensional structure (stereoscopic structure), in which such regions are three-dimensionally formed on the main surface of the silicon substrate.

In the three-dimensional structure, the channel region is formed on a sidewall of a fin or a pillar, which may protrude and extend above the main surface of the silicon substrate, and the source and drain regions are formed at opposite sides of the channel region in the channel length direction. Here, a three-dimensional element body such as the fin or the pillar may be obtained by etching the main surface of the silicon substrate down to a depth of 100 nm or more.

Unlike in the case of a conventional trench etching, the etched sidewall produced by the etching process of such a three-dimensional element is employed as the channel region of the MISFET. Accordingly, if the crystal lattice on the sidewall is damaged due to ion impact, the performance of the MISFET may be significantly deteriorated. In view of the above, it is required that, in the etching process, ions are incident on the substrate with high vertical directivity and a halogen based single gas not-containing carbon and having a high etching selectivity against SiO₂ and SiN, especially, Cl₂ gas, is often employed.

However, if etching the silicon substrate is carried out by using the halogen based gas as the etching gas and an inorganic film containing silicon as the etching mask, and if the main etching mechanism is the sputter etching by ion irradiation, it is difficult to enhance the mask selectivity and further it is more difficult to obtain both the high selectivity and the vertically etched sidewall.

In the etching of a three-dimensional element body, however, it is required to obtain a higher mask selectivity and a more highly vertically etched sidewall than in the trench etching.

### SUMMARY OF THE INVENTION

In view of the above, the present invention provides a dry etching method that can enhance the mask selectivity and obtain both the high selectivity and a highly vertically etched sidewall in an etching process of a silicon substrate, especially in an etching process for forming a three-dimensional structure.

In accordance with an aspect of the present invention, there is provided a dry etching method including: mounting a silicon substrate on an electrode arranged in a processing chamber; generating a plasma by discharging an etching gas in the processing chamber; supplying to the electrode a radio frequency power for attracting ions from the plasma; and etching the silicon substrate by the plasma by using an inorganic mask containing silicon as an etching mask. An absolute value of a self-bias voltage generated in the electrode is equal to or smaller than about 280 V, and wherein the etching is carried out while satisfying the following equation: y≦0.0114x+0.171, where x is a pressure inside the processing chamber and y is a power density of the radio frequency power per unit area of the electrode.

In accordance with an aspect of the present invention, there is provided a dry etching method including: mounting a silicon substrate on an electrode arranged in a processing chamber; generating a plasma by discharging an etching gas in the processing chamber; supplying to the electrode a radio frequency power for attracting ions from the plasma; and etching the silicon substrate by the plasma by using an inorganic mask containing silicon as an etching mask. A temperature of the electrode is set to be equal or to greater than about 85° C. and the etching gas is a gases mixture including a halogen gas and an oxygen gas.

### BRIEF DESCRIPTION OF THE DRAWINGS

The objects and features of the present invention will become apparent from the following description of embodiments, given in conjunction with the accompanying drawings, in which:

FIG. 1 is a vertical cross sectional view showing the structure of a plasma etching apparatus for executing a dry etching method in accordance with the present invention;

FIGS. 2A to 2D are vertical cross sectional views showing one process of an etching of forming a cylindrical pillar-shaped element body by using the dry etching method in accordance with an embodiment of the present invention;

FIG. 3 is a table where parameters used in test examples A1 to A6, respectively, and obtained etching characteristics are listed for the dry etching in accordance with a first experiment of the embodiment;

FIG. 4 is a table where parameters used in comparative examples a1 to a5, respectively, and obtained etching characteristics are listed for the dry etching in accordance with the first experiment of the embodiment;

FIG. 5 is a view in which SEM pictures are mapped according to pressure and bias RF power to show a cross section of each of the etched pillars obtained from the test examples A1 to A6 and the comparative examples a1 to a5;

FIG. 6 shows distribution of the test examples A1 to A6 and the comparative examples a1 to a5 mapped according to two parameter values (pressure and bias RF power) employed therein;

FIG. 7 shows distribution of the test examples A1 to A6 and the comparative examples a1 to a5 mapped according to two parameter values (pressure and self-bias voltage) employed therein;

FIG. 8 is a table where parameters used in test examples B1 to B2 and comparative examples b1 to b3, respectively, and obtained etching characteristics, and SEM pictures are illustrated for a dry etching in accordance with a second experiment of the embodiment; and

FIG. 9 shows etching characteristics obtained from a comparative example b4 in the dry etching in accordance with the second experiment of the embodiment.

### DETAILED DESCRIPTION OF THE EMBODIMENTS

Embodiments of the present invention will now be described with reference to the accompanying drawings which form a part hereof.

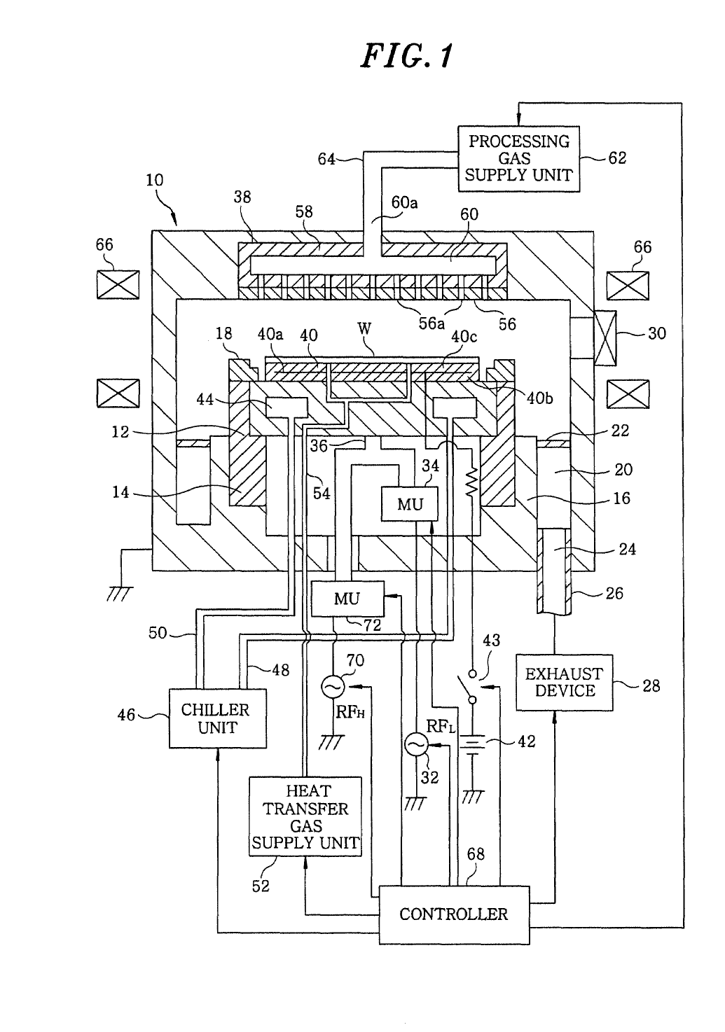

FIG. 1 is a vertical cross sectional view showing the structure of a plasma etching apparatus for executing a dry etching method of the present invention. The plasma etching apparatus is of a capacitively coupled parallel plate type where dual RF frequencies are applied to a lower electrode, and includes a cylindrical chamber (processing chamber) 10 made of a metal, e.g., aluminum, stainless steel or the like. The chamber 10 is frame-grounded.

In the chamber 10, a cylindrical susceptor 12 serving as a lower electrode is placed to mount a target object (i.e. a target substrate) thereon. The susceptor 12, which is made of, e.g., aluminum, is supported by an insulating tubular support 14, which is in turn supported by a cylindrical support 16 vertically extending from a bottom portion of the chamber 10 upwardly. A focus ring 18 made of, e.g., quartz or silicon is arranged on an upper surface of the tubular support 14 to annularly surround a peripheral part of a top surface of the susceptor 12.

An exhaust path 20 is formed between a sidewall of the chamber 10 and the cylindrical support 16. An annular baffle plate 22 is attached to the entrance or the inside of the exhaust path 20, and an exhaust port 24 is disposed at a bottom portion of the chamber 10. An exhaust device 28 is connected to the exhaust port 24 via an exhaust pipe 26. The exhaust device 28 includes a vacuum pump to evacuate an inner space of the chamber 10 to a predetermined vacuum level. Attached to the sidewall of the chamber 10 is a gate valve 30 for opening and closing a gateway through which a silicon wafer W is loaded or unloaded.

A first high frequency power supply 32 for attracting ions is electrically connected to the susceptor 12 via a first matching unit (MU) 34 and a power feed rod 36. The first high frequency power supply 32 supplies a first radio frequency power RF_{L} to the susceptor 12. The first radio frequency power RF_{L} has a frequency that is equal to or smaller than about 13.56 MHz, adequate to attract ions in the plasma to the silicon wafer W.

A second high frequency power supply 70 for generating a plasma is also electrically connected to the susceptor 12 via a second matching unit (MU) 72 and the power feed rod 36. The second high-frequency power supply 70 supplies a second radio frequency power RF_{H} to the susceptor 12. The second radio frequency power RF_{H} has a frequency that is equal to or greater than about 40 MHz, adequate to discharge an etching gas by the radio frequency power.

At a ceiling portion of the chamber 10, a shower head 38 is placed as an upper electrode of ground potential. The first and the second radio frequency power RF_{L} and RF_{H} respectively supplied from the first and second high frequency power supply 32 and 70 are capacitively applied between the susceptor 12 and the shower head 38.

An electrostatic chuck 40 is placed on the top surface of the susceptor 12 to hold the silicon wafer W by an electrostatic force. The electrostatic chuck 40 includes an electrode 40a made of a conductive film and a pair of insulation films 40b and 40c. The electrode 40a is interposed between the insulation films 40b and 40c. A DC power supply 42 is electrically connected to the electrode 40a via a switch 43. By a DC voltage supplied from the DC power supply 42, the silicon wafer W can be attracted to and held by the electrostatic chuck 40 by the Coulomb force.

A coolant chamber 44, which extends in, e.g., a circumferential direction, is installed inside the susceptor 12. A coolant, e.g., a cooling water, of a predetermined temperature is circularly supplied from a chiller unit 46 to the coolant chamber 44 via pipelines 48 and 50. It is possible to control a process temperature of the silicon wafer W held on the electrostatic chuck 40 by adjusting the temperature of the coolant. Moreover, a heat transfer gas, e.g., He gas, is supplied from a heat transfer gas supply unit 52 to a space between a top surface of the electrostatic chuck 40 and a bottom surface of the silicon wafer W through a gas supply line 54.

The shower head 38 placed at the ceiling portion of the chamber 10 includes a lower electrode plate 56 having a plurality of gas injection holes 56a and an electrode support 58 that detachably supports the electrode plate 56. A buffer chamber 60 is provided inside the electrode support 58. A processing gas supply unit 62 is connected to a gas inlet opening 60a of the buffer chamber 60 via a gas supply line 64.

Provided along a circumference of the chamber 10 is a magnet unit 66 extending annularly or concentrically around the chamber 10. In the chamber 10, a high density plasma is generated near the surface of the susceptor 12 by the collective action of an RF electric field, which is produced between the shower head 38 and the susceptor 12 by the second radio frequency power RF_{H}, and a magnetic field generated by the magnet unit 66. In this present embodiment, even though a plasma generation space inside the chamber 10, especially the plasma generation space between the shower head 38 and the susceptor 12 has a low pressure of about 1 mTorr (about 0.133 Pa), it is possible to obtain a high density plasma having electron density of about 1×10¹⁰/cm³ or more in order to execute the dry etching method of the present invention.

A controller 68 controls operations of various parts of the plasma etching apparatus, e.g., the exhaust device 28, the first high frequency power supply 32, the first matching unit 34, the switch 43, the chiller unit 46, the heat transfer gas supply unit 52, the processing gas supply unit 62, the second high frequency power supply 70, the second matching unit 72, and the like. The controller 68 is connected to a host computer (not shown) and the like.

In the plasma etching apparatus, the gate valve 30 is opened first, and a target object, i.e., the silicon wafer W, is loaded in the chamber 10 and mounted on the electrostatic chuck 40 to perform the dry etching. Then, the etching gas is supplied from the processing gas supply unit 62 to the chamber 10 at a predetermined flow rate and flow rate ratio, and the pressure inside the chamber 10 is adjusted by the exhaust device 28 at a preset level. Moreover, the first radio frequency power RF_{L} having a preset level is supplied from the first high frequency power supply 32 to the susceptor 12 and the second radio frequency power RF_{H} having a preset level is supplied from the second radio frequency power supply 70 to the susceptor 12.

A DC voltage is supplied from the DC power supply 42 to the electrode 40a of the electrostatic chuck 40 so that the silicon wafer W is firmly mounted on the electrostatic chuck 40. The etching gas injected from the shower head 38 is glow-discharged between the electrodes 12 and 38 to thereby be converted into a plasma. Radicals or ions generated in the plasma pass through openings in an etching mask on the surface of the silicon wafer W and react with the target object (e.g., the silicon substrate), thereby etching the target object in a desired pattern.

In such a dry etching process, the radio frequency power RF_{H} having a relatively high frequency (e.g., about 40 MHz or more, and preferably about 80 MHz to 300 MHz) supplied from the second radio frequency power supply 70 to the susceptor (lower electrode) 12 mainly contributes to the discharge of the etching gas or the generation of the plasma; and the first radio frequency power RF_{L} having a relatively low frequency (e.g., about 27 MHz or less, or preferably about 2 MHz to 13.56 MHz) supplied from the first high frequency power supply 32 to the susceptor (lower electrode) 12 mainly contributes to ion attraction from the plasma to the silicon wafer W.

During the dry etching, that is, while the plasma is generated in the processing space, a lower ion sheath is formed between the bulk plasma and the susceptor (lower electrode) 12. As a result, a negative self-bias voltage V_{dc}, having the substantially same magnitude as a voltage drop of the lower ion sheath, is produced at the susceptor 12 and the silicon wafer W. An absolute value |V_{dc}| of the self-bias voltage is in proportion to a peak-to-peak value Vₚₚ of the voltage of the first radio frequency power RF_{L} supplied to the susceptor 12.

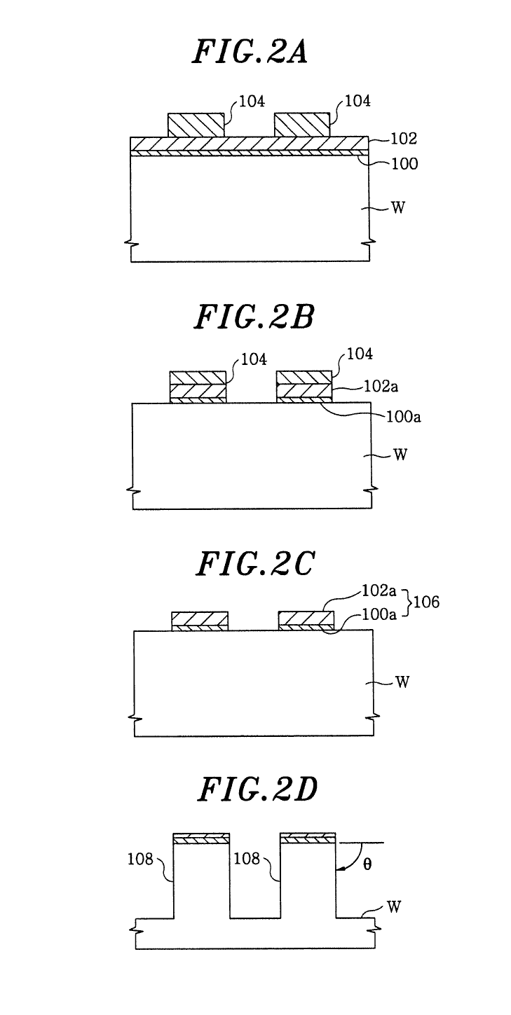

As an example of the etching process to which the present invention can be adequately applied, a dry etching method for forming a pillar-shaped element body for a vertical transistor on a main surface of the silicon wafer W in accordance to the embodiments of the present invention will be described below with reference to FIGS. 2A to 9.

As shown in FIG. 2A, in order to form such kind of pillar-shaped element body, a thin silicon oxide (SiO₂) film 100 is first formed on the main surface of the silicon wafer W by a thermal oxidation or a chemical vapor deposition (CVD) and a silicon nitride (SiN) film 102 is formed on the SiO₂ film 100 by the CVD. A resist is formed on the SiN film 102 and then is patterned into a patterned resist 104 of, e.g., a circle shape by lithography.

Then, as shown in FIG. 2B, the SiN film 102 and the SiO₂ film 100 are etched and patterned in that order by using the patterned resist 104 as an etching mask.

Thereafter, as shown in FIG. 2C, the patterned resist 104 is removed by ashing to expose a stacked inorganic mask 106 including a patterned SiN film 102a (top layer) and a patterned SiO₂ film 100a (bottom layer).

Subsequently, the silicon wafer W is etched down to a desired depth by using the inorganic mask 106 as an etching mask as shown in FIG. 2D to form a cylindrical pillar-shaped element body (referred to as pillar hereinafter) 108.

The SiO₂ film 100a forming the bottom layer of the inorganic mask 106 serves to alleviate the stress on the SiN film 102a (top layer). SiN is a main constituent for the mask.

Below are the important requirements for the silicon dry etching to form the pillar-shaped element body 108. First, damage to a sidewall of the pillar 108 by ion impact or ion incidence thereon needs to be minimized or completely avoided. Second, the sidewall of the pillar 108 needs to be etched to be as vertical as possible. (ideally, a taper angle θ is 90°). Finally, the mask selectivity needs to be sufficiently large (practically, equal to or greater than about 4.0 or more).

### (First Experiment)

In a first experiment, an etching experiment of forming the pillar-shaped element body 108 was performed by executing the dry etching of the silicon wafer W under various conditions by using the plasma etching apparatus shown in FIG. 1. The experiment was carried out by changing three parameters, i.e., the pressure of the chamber 10, the power (bias RF power) of the first radio frequency power RF_{L} for ion attraction, and the self-bias voltage V_{dc}. Main conditions are as follows.

Diameter of silicon wafer: 300 mm

Etching mask: SiN (150 nm) on SiO₂

Etching gas: Cl₂ gas of 100 sccm

Chamber pressure: 3 mTorr to 100 mTorr

First radio frequency power: 13 MHz, and bias RF power of 100 W to 800 W

Second radio frequency power: 100 MHz, and RF power of 500 W

Self-bias voltage V_{dc}: −480 V to −130 V

Distance between upper and lower electrodes: 30 mm

Area of lower electrode: 706.5 cm² (Diameter: 300 mm)

Temperature: upper electrode/sidewall of chamber/lower electrode=80/70/85° C.

Etching time: 30 seconds to 79 seconds

### TEST EXAMPLES

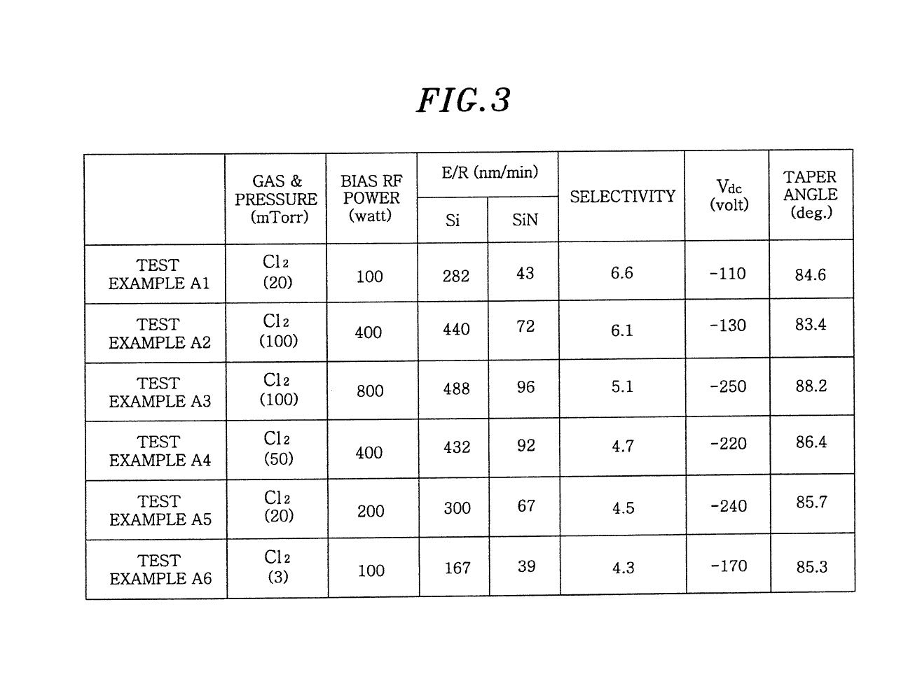

FIG. 3 is a table where parameters used in test examples A1 to A6 and obtained etching characteristics are listed.

### Test Examples A1

The gas pressure was 20 mTorr; the bias RF power was 100 W; and the self-bias voltage V_{dc} was −110 V. The mask selectivity of 6.6 and the taper angle θ of 84.6° were obtained.

### Test Example A2

The gas pressure was 100 mTorr; the bias RF power was 400 W; and the self-bias voltage V_{dc} was −130 V. The mask selectivity of 6.1 and the taper angle θ of 83.4° were obtained.

### Test Example A3

The gas pressure was 100 mTorr; the bias RF power was 800 W; and the self-bias voltage V_{dc} was −250 V. The mask selectivity of 5.1 and the taper angle θ of 88.2° were obtained.

### Test Example A4

The gas pressure was 50 mTorr; the bias RF power was 400 W; and the self-bias voltage V_{dc} was −220 V. The mask selectivity of 4.7 and the taper angle θ of 86.4° were obtained.

### Test Example A5

The gas pressure was 20 mTorr; the bias RF power was 200 W; and the self-bias voltage V_{dc} was −240 V. The mask selectivity of 4.5 and the taper angle θ of 85.7° were obtained.

### Test Example A6

The gas pressure was 3 mTorr; the bias RF power was 100 W; and the self-bias voltage V_{dc} was −170 V. The mask selectivity of 4.3 and the taper angle θ of 85.3° were obtained.

### COMPARATIVE EXAMPLES

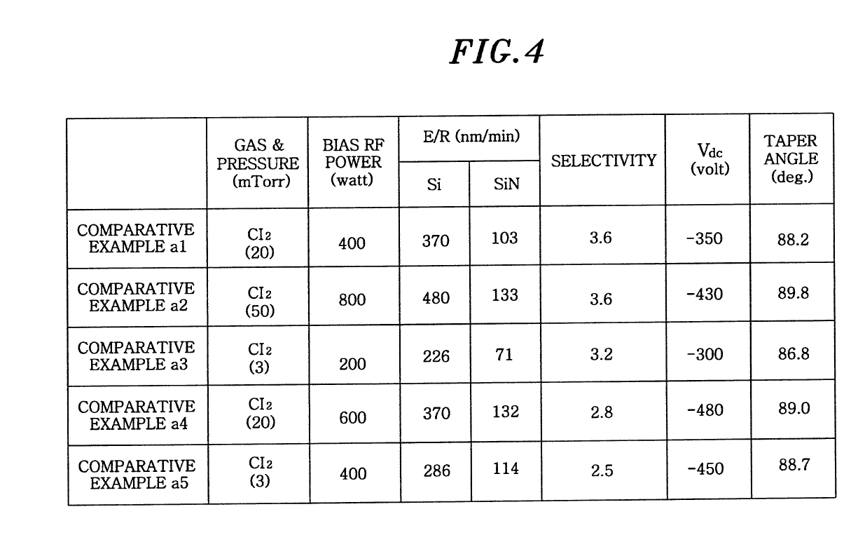

FIG. 4 is a table where parameters used in the comparative examples a1 to a5 and obtained etching characteristics are listed.

### Comparative Example a1

The gas pressure was 20 mTorr; the bias RF power was 400 W; and the self-bias voltage V_{dc} was −350 V. The mask selectivity of 3.6 and the taper angle θ of 88.2° were obtained.

### Comparative Example a2

The gas pressure was 50 mTorr; the bias RF power was 800 W; and the self-bias voltage V_{dc} was −430 V. The mask selectivity of 3.6 and the taper angle θ of 89.8° were obtained.

### Comparative Example a3

The gas pressure was 3 mTorr; the bias RF power was 200 W; and the self-bias voltage V_{dc} was −300 V. The mask selectivity of 3.2 and the taper angle θ of 86.8° were obtained.

### Comparative Example a4

The gas pressure was 20 mTorr; the bias RF power was 600 W; and the self-bias voltage V_{dc} was −480 V. The mask selectivity of 2.8 and the taper angle θ of 89.0° were obtained.

### Comparative Example a5

The gas pressure was 3 mTorr; the bias RF power was 400 W; and the self-bias voltage V_{dc} was −450 V. The mask selectivity of 2.5 and the taper angle θ of 88.7° were obtained.

As described above, the mask selectivities of the test examples A1 to A6 were equal to or greater than 4.0 which is practically acceptable. In contrast, the mask of the comparative examples a1 to a5 had unacceptably large values of smaller than 4.0.

Since, in the etching processes of the above experiment, a single gas Cl₂ was used as the etching gas, and the inorganic mask 106 of SiN/SiO₂ not containing hydrogen and carbon was used as the etching mask, vertical etching by ion irradiation is predominantly made with anisotropy. Accordingly, the vertical slopes of etched sidewalls are with the acceptable range (i.e., taper angle θ being equal to or greater than 85°) in all the test examples A1 to A6 and comparative examples a1 to a5. Moreover, as the taper angle θ of the sidewall is made closer to 90°, the sidewall becomes less subject to ion impact or ion incidence thereto, leading to small sidewall damage.

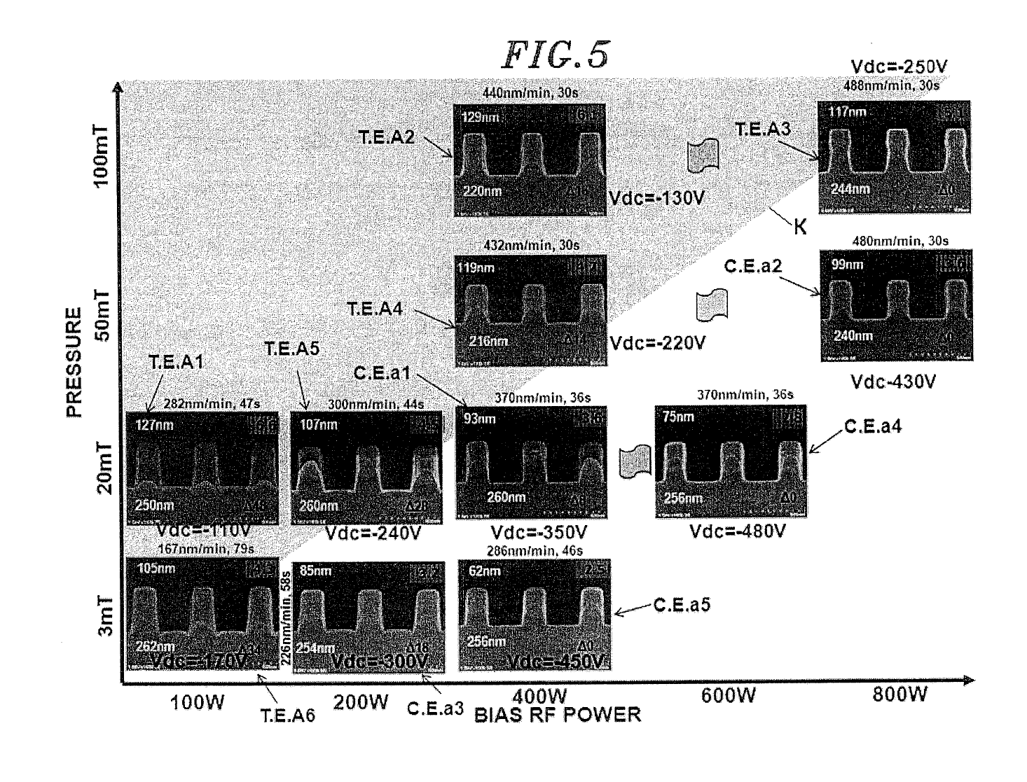

FIG. 5 is a view in which SEM pictures are mapped according to pressure and bias RF power to show a cross section of each of the etched pillars obtained from the test examples A1 to A6 and the comparative examples a1 to a5, where the horizontal axis is the bias RF power and the vertical axis is the pressure.

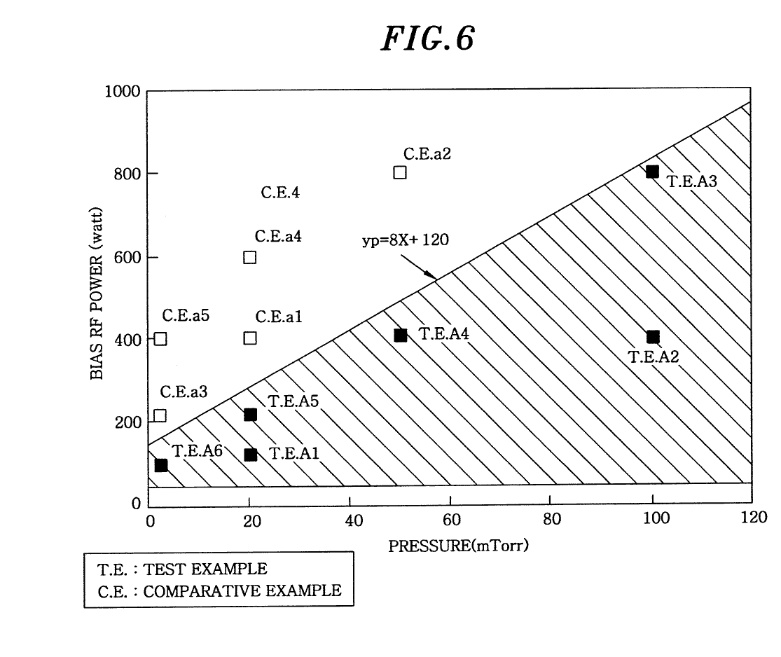

FIG. 6 shows distribution of the test examples A1 to A6 and the comparative examples a1 to a5 mapped according to two parameter values (pressure and bias RF power) employed therein. As shown in FIG. 6, when the pressure (mTorr) is represented as x and the bias RF power (watt) is represented as yP, all the test examples A1 to A6 are distributed below a straight line of yP=8x+120, but all the comparative examples a1 to a5 are distributed above that line. Meanwhile, the straight line of yP=8x+120 shown in FIG. 6 approximately coincides with a straight line K shown in FIG. 5.

Accordingly, it can be seen from the present experiment that satisfactory results can be obtained if the relationship between the pressure x and the bias RF power yP satisfies the following Eq. 1:

yP<8x+120 Eq. 1.

The bias RF power yP can be converted to the power per unit area of the susceptor (i.e., lower electrode) 12, i.e., bias RF power density yM (watt/cm²).

In the present experiment, if it is assumed that the diameter of the susceptor 12 is approximately identical to that of the wafer (i.e., 300 mm), the area of lower electrode is 706.5 cm², which yields the relationship between the bias RF power yP and the bias RF power density yM as follows:

yP=706.5*yM Eq. 2.

By using Eq. 2, the above Eq. 1 can be converted to the following Eq. 3:

yM<0.0114x+0.171 Eq. 3.

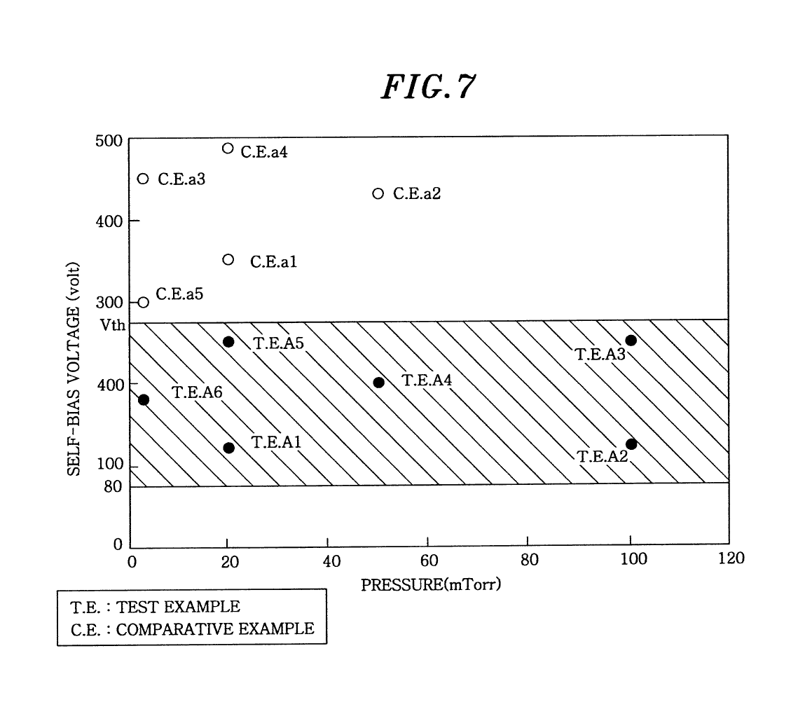

FIG. 7 shows distribution of the test examples A1 to A6 and the comparative examples a1 to a5 mapped according to two parameter values (pressure and self-bias voltage) employed therein. As shown in FIG. 7, when an absolute value of the self-bias voltage is represented as |V_{dc}|, |V_{dc}| has a threshold value Vₜₕ, i.e., 280 V. All the test examples A1 to A6 are distributed below the threshold value Vₜₕ, but the comparative examples a1 to a5 are distributed above the threshold value Vₜₕ regardless of the pressure.

Accordingly, it can be seen from the first experiment that satisfactory results can be obtained if the absolute value |V_{dc}| of the self-bias voltage is equal to or smaller than 280 V regardless of the pressure and, preferably, 150V as in the case of having the selectivity of 6.0 or more. However, if |V_{dc}| is smaller than 80 V, the ion energy is too low to obtain the high vertical processability. Accordingly, the optimum condition of |V_{dc}| may satisfy the following Eq. 4:

80V≦|V_{dc}|≦280V Eq. 4.

As described above, in accordance with the first experiment, it is possible to meet the aforementioned three requirements for the silicon dry etching by setting the conditions such that the pressure x, the bias RF power density yM and the absolute value |V_{dc}| of the self-bias voltage satisfy the above Eqs. 3 and 4 when etching a silicon three-dimensional element body by employing the single gas Cl₂ as the etching gas and the inorganic mask of Silicon nitride (SiN) as the etching mask.

### (Second Experiment)

In a second experiment, an etching experiment of forming the pillar-shaped element body 108 was performed by executing the dry etching of the silicon wafer W under various conditions by using the plasma etching apparatus shown in FIG. 1. The experiment was carried out by changing a susceptor temperature (i.e., a wafer temperature) and a ratio of flow rates of O₂ and Cl₂. Main conditions are as follows.

Diameter of silicon wafer: 300 mm

Etching mask: SiN (150 nm) on SiO₂

Etching gas: single gas of Cl₂ or a gaseous mixture of Cl₂ and O₂

Flow rates: Cl₂ gas=100 sccm, O₂ gas=0, 5, and 10 sccm

Chamber pressure: 20 mTorr

First radio frequency power: 13 MHz, and bias power of 400 W

Second radio frequency power: 100 MHz, and RF power of 500 W

Self-bias voltage V_{dc}: −350 V

Distance between upper and lower electrodes: 30 mm

Area of lower electrode: 706.5 cm² (Diameter: 300 mm)

Temperature: upper electrode/sidewall of chamber/lower electrode=80/70/15, 40, 85° C.

Etching time: 30 seconds to 79 seconds

### TEST AND COMPARATIVE EXAMPLES

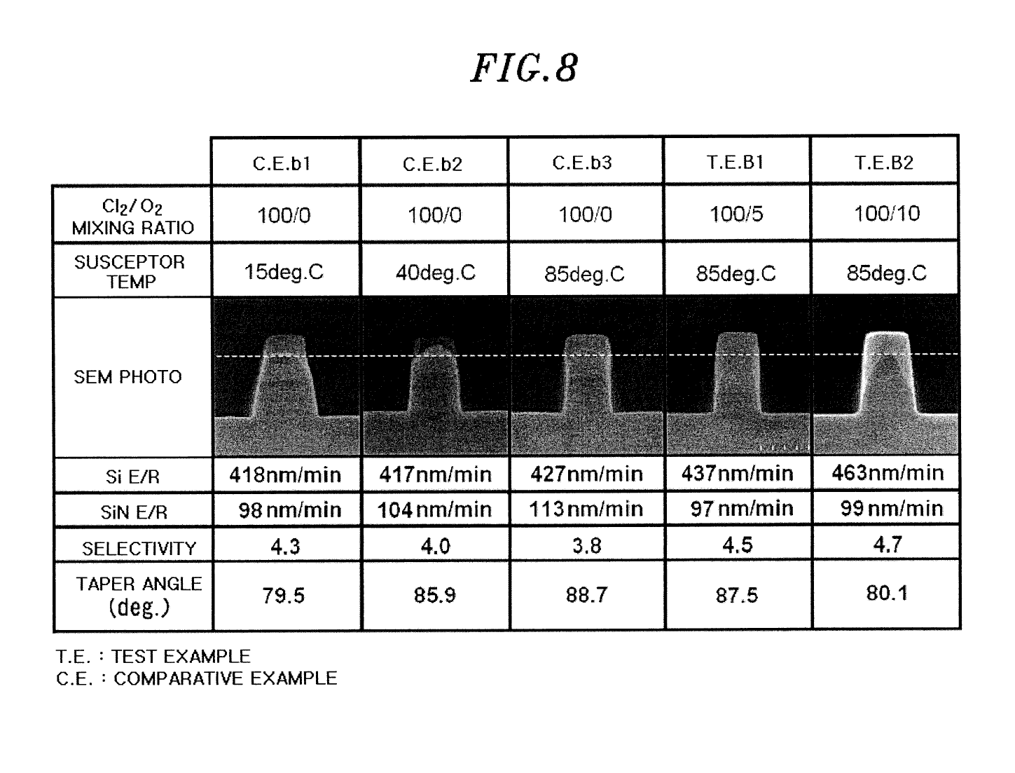

FIG. 8 is a table where parameters used in test examples B1 and B2 and comparative examples b1 to b3, respectively, and obtained etching characteristics, and SEM pictures are illustrated.

### Comparative Example b1

The mixing (flow rate) ratio of Cl₂ and O₂ gas was 100/0 and the susceptor temperature (wafer temperature) was 15° C. The mask selectivity of 4.3 and the taper angle θ of 79.5° were obtained.

### Comparative Example b2

The mixing ratio of Cl₂ and O₂ gas was 100/0 and the susceptor temperature was 40° C. The mask selectivity of 4.0 and the taper angle θ of 85.9° were obtained.

### Comparative Example b3

The mixing ratio of Cl₂ and O₂ gas was 100/0 and the susceptor temperature was 85° C. The mask selectivity of 3.8 and the taper angle θ of 88.7° were obtained.

### Test Example B1

The mixing ratio of Cl₂ and O₂ gas was 100/5 and the susceptor temperature was 85° C. The mask selectivity of 4.5 and the taper angle θ of 87.5° were obtained.

### Test Example B2

The mixing ratio of Cl₂ and O₂ gas was 100/10 and the susceptor temperature was 85° C. The mask selectivity of 4.7 and the taper angle θ of 80.1° were obtained.

As described above, when the single gas of Cl₂ was used as the etching gas as in the comparative examples b1 to b3, it can be seen that, as the temperature of susceptor (temperature of the wafer) is increased from 15° C. to 40° C. and 80° C., the sidewall shape of the pillar is changed from a taper shape to a vertical or a bowing shape and the mask selectivity is lowered from 4.3 to 4.0 and 3.8. Further, it can be seen that it is possible to enhance both the vertical processbility of the etched sidewall and the mask selectivity by adding an adequate amount of O₂ while maintaining the susceptor temperature at the high temperature level (85° C.) as in the test examples B1 and B2.

As such, when adding an adequate amount of the O₂ gas at the high temperature level (85° C.), nonvolatile SiO₂ produced by the oxidation reaction of silicon is deposited on the sidewall as a protecting film, thereby preventing the bowing.

The reaction product SiO₂ is deposited on a mask surface and an etched bottom surface as well, but the mask surface and the etched bottom surface are easy to be sputtered by the ion irradiation. Since, however, the etched bottom surface (silicon wafer) becomes more subject to the sputtering as compared with the mask surface (SiN), the mask selectivity can be enhanced.

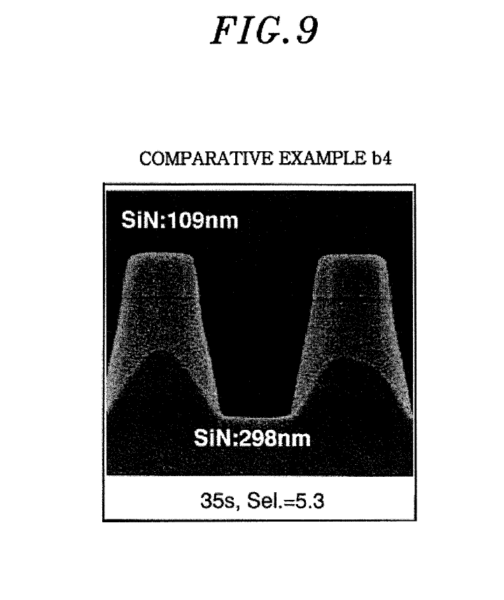

However, when a greater amount of O₂ is added to the etching gas Cl₂, e.g., the mixing (flow rate) ratio of Cl₂ and O₂ gas at the susceptor temperature of 85° C. is 100/20, the mask selectivity is further enhanced to 5.3, while the sidewall protection effect is excessively increased and thus the sidewall shape of the pillar is returned to the taper shape, as in comparative example b4 shown in FIG. 9.

Accordingly, when the susceptor temperature is 85° C., the mixing ratio of the O₂ gas to the Cl₂ gas needs to be set as 5% to 10% as in the test examples B1 and B2. Further, in the above experiment, as the susceptor temperature becomes higher, the etching rate (E/R) of the sidewall by chlorine radicals is increased. Accordingly, the mixing ratio of the O₂ gas to the Cl₂ gas needs to be largely increased further to suppress the increase in the etching rate. When the susceptor temperature is higher than 100° C. for example, the mixing ratio of the O₂ gas to the Cl₂ gas may be set as 10% to 15%.

In the plasma etching apparatus shown in FIG. 1, it is possible to arbitrarily set or control the susceptor temperature by adjusting the coolant temperature of the chiller unit 46. The susceptor temperature, however, has an upper limit. For example, if the susceptor temperature is beyond 150° C., the patterned resist 104 serving as the etching mask may be deformed by heat during the processing steps of the pillar-shaped element body as shown in FIGS. 2A to 2D. Accordingly, the susceptor temperature needs to be maintained to be lower than 150° C. practically.

Meanwhile, in the test examples B1 and B2 of the second experiment, absolute values |V_{dc}| of the self-bias voltages were beyond the condition (range) of Eq. 4. This indicates that when the O₂ gas is added to the Cl₂ gas, the ion energy (e.g., |V_{dc}|) can be increased to balance the action that the reaction product SiO₂ is deposited on the surface to be etched.

With the above configurations and functions in the embodiments of the present invention, it is possible to enhance the mask selectivity and obtain both the high selectivity and a highly vertically etched sidewall in an etching process of a silicon substrate, especially in an etching process for forming a three-dimensional structure.

While the invention has been shown and described with respect to the embodiments, it will be understood by those skilled in the art that various changes and modification may be made without departing from the scope of the invention as defined in the following claims.

For example, though it is most preferable to employ Cl₂ gas as the etching gas of the embodiments, it is possible to use other halogen gas such as fluorine (F₂) gas, bromine (Br₂) gas, and iodine (I₂) gas. Alternatively, the etching gas can be a gases mixture in which halogen gas and inactive gas or noble gas such as helium, argon, or the like are mixed. It is also preferable that the gas that is added to the etching gas is the O₂ gas, but N₂ gas or other gases yielding the same effect may be employed.

The plasma etching apparatus usable for the dry etching method in accordance with the embodiments of the present invention is not limited to the aforementioned embodiments, but various modifications are possible. For example, it is possible to use an upper-and-lower plate dual frequency application type plasma etching apparatus, which a high frequency power for plasma generation is applied to an upper electrode and a high frequency power for ion attraction is applied to a lower electrode. In addition to a capacitively coupled plasma etching apparatus, it is possible to use, e.g., an inductively coupled plasma etching apparatus, which has an antenna arranged on an upper surface of a chamber or around the chamber and generates a plasma by an induced electromagnetic field, and a microwave plasma etching apparatus, which generates a plasma by using a microwave power.

What is claimed is:

1. A dry etching method comprising:
mounting a silicon substrate on an electrode arranged in a processing chamber;
generating a plasma by discharging an etching gas in the processing chamber;
supplying to the electrode a radio frequency power for attracting ions from the plasma; and
etching the silicon substrate by the plasma by using an inorganic mask containing silicon as an etching mask,
wherein an absolute value of a self-bias voltage generated in the electrode is equal to or smaller than about 280 V, and
wherein the etching is carried out while satisfying the following equation:
y≦0.0114x+0.171,
where x is a pressure inside the processing chamber and y is a power density of the radio frequency power per unit area of the electrode.

2. The method of claim 1, wherein the absolute value of the self-bias voltage generated in the electrode is set as about 80 V to 280 V.

3. The method of claim 1, wherein the pressure inside the processing chamber is set as about 3 mTorr to 100 mTorr.

4. The method of claim 1, wherein the etching gas includes a halogen etchant gas.

5. The method of claim 4, wherein the halogen gas is a chlorine gas.

6. The method of claim 1, wherein a temperature of the electrode is equal or to greater than about 85° C.

7. The method of claim 1, wherein an electron density of the plasma is equal to or greater than about 1*10¹⁰ cm³.

8. The method of claim 1, wherein an additional electrode is placed in the processing chamber in parallel with the electrode with a gap therebetween and an additional radio frequency power for discharging the etching gas is supplied to the electrode or the additional electrode.

9. The method of claim 8, wherein the radio frequency power has a frequency of about 2 MHz to 13.56 MHz, and the additional radio frequency power has a frequency of about 40 MHz to 300 MHz.

10. The method of claim 1, wherein a three-dimensional element body having a cylindrical or a rectangular parallelepiped shape is formed on a main surface of the silicon substrate by the etching.

11. A dry etching method comprising:
mounting a silicon substrate on an electrode arranged in a processing chamber;
generating a plasma by discharging an etching gas in the processing chamber;
supplying to the electrode a radio frequency power for attracting ions from the plasma; and
etching the silicon substrate by the plasma by using an inorganic mask containing silicon as an etching mask,
wherein a temperature of the electrode is set to be equal or to greater than about 85° C. and the etching gas is a gases mixture including a halogen gas and an oxygen gas.

12. The method of claim 11, wherein an absolute value of the self-bias voltage generated in the electrode is set to be equal to or greater than about 280 V.

13. The method of claim 12, wherein, as the temperature of the electrode is set higher, a mixing ratio of the oxygen gas to the halogen gas is increased.

14. The method of claim 11, wherein the temperature of the electrode is set as about 85° C. to 100° C. and the mixing ratio of the oxygen gas to the halogen gas is set as about 5% to 10%.

15. The method of claim 11, wherein the temperature of the electrode is set as about 100° C. to 150° C. and the mixing ratio of the oxygen gas to the halogen gas is set as about 10% to 15%.

16. The method of claim 11, wherein the halogen gas is a chlorine gas.

17. The method of claim 11, wherein an electron density of the plasma is equal to or greater than about 1*10¹⁰ cm³.

18. The method of claim 11, wherein an additional electrode is placed in the processing chamber in parallel with the electrode with a gap therebetween and an additional radio frequency power for discharging the etching gas is supplied to the electrode or the additional electrode.

19. The method of claim 18, wherein the radio frequency power has a frequency of about 2 MHz to 13.56 MHz, and the additional radio frequency power has a frequency of about 40 MHz to 300 MHz.

20. The method of claim 11, wherein a three-dimensional element body having a cylindrical or a rectangular parallelepiped shape is formed on a main surface of the silicon substrate by the etching.
